(19) United States
(12) Patent Application Publication
(10) Pub. No.: US 2025/0181814 A1
(43) Pub. Date: Jun. 5, 2025

(54) DIFFERENTIABLE GLOBAL ROUTER

(71) Applicant: NVIDIA Corp., Santa Clara, CA (US)

(72) Inventors: Rongjian Liang, Austin, TX (US); Haoxing Ren, Austin, TX (US); Wei Li, Pittsburgh, PA (US)

(73) Assignee: NVIDIA Corp., Santa Clara, CA (US)

(21) Appl. No.: 18/965,415

(22) Filed: Dec. 2, 2024

Related U.S. Application Data
(60) Provisional application No. 63/606,499, filed on Dec. 5, 2023.

(51) Int. Cl. G06F 30/394; G06N 3/042; G06N 3/047; G06N 3/048

(52) U.S. Cl. CPC G06F 30/394; G06N 3/042; G06N 3/047; G06N 3/048

(57) ABSTRACT

Mechanisms for generating metal routing guides in a circuit involve forming a plurality of directed acyclic graphs (DAGs) embodying routing trees for nets in the circuit, generating 2-pin subnets and 2-pin path candidates from the routing trees, and forming a DAG forest from the routing trees, the 2-pin subnets, and the 2-pin path candidates.

### CROSS-REFERENCE TO RELATED APPLICATIONS

The application claims priority and benefit under 35 U.S.C. 119(e) to U.S. Application Ser. No. 63/606,499, titled “Differentiable Global Router” and filed on Dec. 5, 2023, the contents of which are incorporated herein by reference in their entirety.

### BACKGROUND

The routing of metal tracks in large-scale circuits involves the generation of coarse-grain routing guides (global routing), and the assignment of routing tracks for all connections according to the routing guides while ensuring compliance with design rule constraints (detailed routing). The efficiency and accuracy of the global routing influences the efficiency of detailed routing and the overall quality of post-route circuits. Additionally, the efficiency of global routing facilitates timing-driven and congestion-driven component placement by providing accurate interconnect information for placement tools. Consequently, modern circuit design workflows may rely on fast and high-quality global routing mechanisms.

Conventional global routers may utilize a Directed Acyclic Graph (DAG) and dynamic pattern routing optimization on each circuit net. However, when such a router is operated sequentially, meaning it operates on a single net of the circuit at a time, it may not provide optimal routing solutions for all nets in the circuit. Combinatorial optimization-based global routers may concurrently optimize multiple nets but these types of routers often incur high computational costs.

### BRIEF DESCRIPTION OF THE SEVERAL VIEWS OF THE DRAWINGS

To easily identify the discussion of any particular element or act, the most significant digit or digits in a reference number refer to the figure number in which that element is first introduced.

FIG. 1A depicts an exemplary circuit net.

FIG. 1B depicts an exemplary routing tree for the circuit net depicted in FIG. 1A.

FIG. 1C depicts an exemplary L-shape directed acyclic graph for the routing tree depicted in FIG. 1B.

FIG. 1D depicts a spanning tree for the directed acyclic graph depicted in FIG. 1C.

FIG. 2 depicts an example operation of a differentiable solver.

FIG. 3 depicts high-level operation of a differentiable global router in one embodiment.

FIG. 4 depicts components of a differentiable global router in one embodiment.

FIG. 5 depicts a parallel processing unit 502 in accordance with one embodiment.

FIG. 6 depicts a general processing cluster 600 in accordance with one embodiment.

FIG. 7 depicts a memory partition unit 700 in accordance with one embodiment.

FIG. 8 depicts a streaming multiprocessor 800 in accordance with one embodiment.

FIG. 9 depicts a processing system 900 in accordance with one embodiment.

FIG. 10 depicts an exemplary processing system 1000 in accordance with another embodiment.

### DETAILED DESCRIPTION

In global routing, a two-dimensional routing solution space may be defined. The two-dimensional routing solution space may comprise uniform-sized cells bounded by horizontal and vertical grid lines, i.e., a grid graph. Each cell in a grid graph G(V, E) is assigned a vertex (v∈V) and edges (e∈E) are established between vertices of neighboring cells.

The global router may establish a routing path for each net within the grid graph using a process that ensures the interconnection of all pins in the net. Ideally, the routing paths thus formed do not overflow their capacity and have a minimal total wire length and a minimal utilization of vias. The global router may also provide guidance to a subsequently-operated detailed router. A quality score for the detailed routing may be utilized as a metric for the efficiency of the global router.

Disclosed herein are embodiments of a differentiable global router providing concurrent routing for many (e.g., millions) of nets. A routing DAG forest structure is formed to represent the two-dimensional global solution space for the nets in a circuit. The differentiable global router utilizes the DAG forest structure to make a coordinated selection of DAGs and DAG edges with global scope.

To enable scalable search in the DAG forest, the solution search space is made continuous and a differentiable solver is applied. In one embodiment, gradient algorithms utilized by the differentiable solver may be accelerated by applying functionality from toolkits such as Pytorch. Pyrorch is an open-source machine learning library developed by Facebook's® AI Research lab. Pytorch provides tools for deep learning and tensor computation with extensive support for GPU acceleration.

The deep learning component may be configured with a sigmoid activation and an Adam optimizer for the weights w. The differentiable solver may select DAGs from the DAG forest in a manner that reduces overflow compared to conventional global routers, thereby avoiding unnecessary rip-up-and-reroute iterations of the router.

The search of the routing DAG forest for candidate routing DAGs may be followed by layer assignment. Embodiments of the disclosed differentiable global routers may apply a Gumbel-Softmax mechanism with temperature annealing effects and top-p selection to improve the routing solution quality.

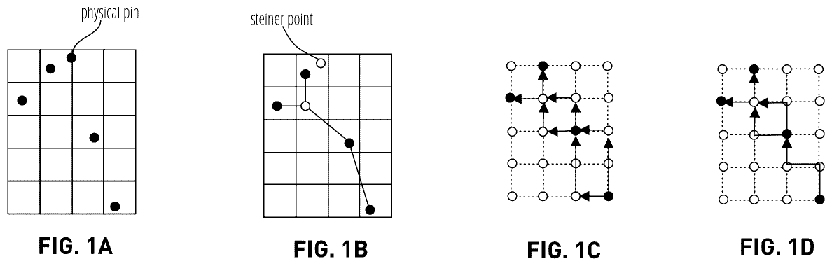

FIG. 1A depicts an exemplary circuit net, and FIG. 1B-FIG. 1D depict the construction of a routing DAG and spanning tree for the depicted circuit net. The routing DAG embodies the structure of available pattern routing paths for the net. In FIG. 1B a rectilinear Steiner minimum tree (RSMT) is formed that connects all pins in the net and that devises a multi-pin net into two-pin sub-nets. Subsequently, routing paths conforming to available patterns are established for each 2-pin sub-net.

One example of a final routing DAG depicted in FIG. 1C comprises vertices embodying pins, Steiner points, or turning points, and further comprises edges embodying interconnect wire segments within routing paths.

A Steiner point is a point object used within the context of the Steiner tree problem. Given a set of points (terminals) in a plane, the goal is to connect all the points utilizing the a network of lines with a minimal total length. A Steiner point is an additional point, not part of the original set, that is added to create a more efficient network by reducing the total length of the connections. The Steiner tree thus formed is often shorter than the minimum spanning tree, which only uses the original points.

Unlike conventional approaches, the disclosed circuit routing mechanisms utilize a directed acyclic graph forest structure. The DAG forest is a structure encoding a two-dimensional (2D) global routing solution space for the nets in a circuit.

In a DAG forest a particular net may be associated with multiple routing DAGs, each embodying a distinct candidate routing topology for that net. Within each routing DAG, vertices represent pins and Steiner points, and edges represent potential 2D routing paths for two-pin sub-nets based on the represented routing topology.

The routing topologies embodied by the DAGs may include, for example, L-/Z-/and C-shape pattern routing, monotonic routing, or even maze routing. The DAG forest encoding of the global routing solution space enables the differentiable global router to make a global-scope, coordinated selection of DAGs and DAG edges for all the nets in a circuit.

The differentiable global router makes a selection from among the candidate routing DAGs for each net. Within the chosen DAG for a net, a spanning tree selection is made. As depicted for example in FIG. 1D, a spanning tree in a DAG comprises a selection of one routing path for each 2-pin sub-net within the DAG.

The DAG forest structure concisely encodes the routing solution space for the nets in a circuit. A single net may be associated with a set of multiple routing DAGs, with each DAG in the set signifying a distinct candidate routing tree topology for that net. Within each candidate routing DAG for a net, individual edges represent potential 2D routing path candidates for 2-pin sub-nets.

For each net the differentiable global router may select from the DAG forest a routing DAG from the candidate routing topologies for the net. The differentiable global router may then choose one 2-pin path for each 2-pin sub-net within the selected DAG. The differentiable global router makes these selections based on minimizing the total wire length, via count, and routing overflow.

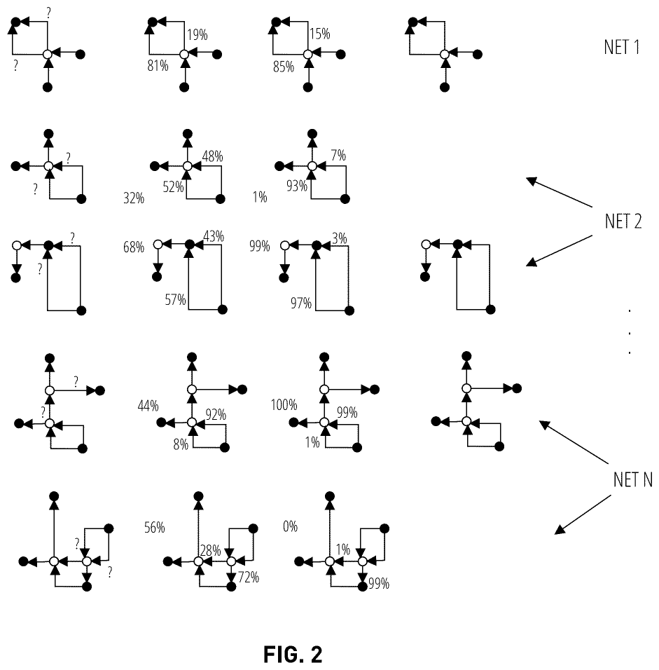

The differentiable global router is configured to operate on a continuous search space within the DAG forest. This enables the router to be more scalable and efficient at performing the search. The differentiable global router may comprise an end-to-end differentiable solver accelerated by deep learning. To bridge between the continuous search space utilized by the differentiable global router and the discrete routing solutions in the DAG forest, a Gumbel-Softmax mechanism with temperature annealing and top-p selection may be applied. An example of the operation of the end-to-end differentiable solver is depicted in FIG. 2.

In one embodiment, an objective is configured in a differentiable global router to select routing DAGs and 2-pin paths (edges in the selected DAGs) for the nets in a circuit to route, such that the total wire length, number of vias, and overflow are minimized overall.

Let N be the set of nets to route in a circuit. A DAG forest F={T, S, P} comprises a routing tree candidate pool T, a set S of 2-pin sub-nets in the routing trees, and a 2-pin path candidate pool P.

Let i∈P be a specific 2-pin path candidate. Then subnet(i)∈S denotes the corresponding 2-pin sub-net of i. Tree(i)∈T denotes the corresponding routing tree of i, and xᵢ∈{0, 1} is a binary setting indicating if i is selected. Thus xᵢ=1 if and only if 2-pin routing path i is selected after global routing.

Let j∈T be a specific routing tree candidate, then net(j)∈N denotes the corresponding net of j, and yⱼ∈{0, 1} is a binary indicator indicating if j is selected. Thus, yⱼ=1 if and only if routing tree j is selected after global routing.

Let E denote the set of grid cell edges in the DAG forest, and let e∈E denote a specific grid cell edge. A capacity metric for edge e, denoted as capₑ, may be configured as:

$${cap}_{e} = {track}_{e} - {β}_{v} * {pin\_density}_{v} - {local\_net}_{e}$$

where:
   trackₑ is the number of available tracks in e.
   pin_densityᵥ is the number of pins in a grid cell v that is connected to e.
   βᵥ is a weight value applied to the pin density. This weigh may for example be determined using conventional design tools from a configured minimal edge length and as well as the physical lengths of edges connecting v.
   local_netₑ denotes the number of local nets at e, i.e., nets with an extent contained within e.

The second term (βᵥ*pin_densityᵥ) and the third term (local_netₑ) reflect the influence of pin connections and local nets to detailed routing quality. A demand metric for edge e, denoted as dₑ, may be configured as:

$${d}_{e} = {\sum }_{i ∈ {P}_{e}} {y}_{tree} ( i ) {x}_{i} + {β}_{v} ( {\sum }_{k ∈ {P}_{v}} {y}_{tree} ( k ) {x}_{k} )$$

in which:
   Pₑ is the set of 2-pin path candidate passing through e.
   Pᵥ is the set of 2-pin path candidate with a turning point at v.
   βᵥ is the weight discussed above.

The demand calculation comprises two terms. The first term reflects the influence of wires that pass through the edge. The second term reflects the influence of vias (vertical metal paths between routing layers).

The DAG forest-based 2D differentiable global router objective may be configured as:

$${min}_{i ∈ P , j ∈ T} {a}_{1} * WL\_cost + {a}_{2} * via\_cost + {a}_{3} * overflow\_cost \\ in which \\ WL\_cost = {\sum }_{i ∈ P} {y}_{tree} ( i ) {WL}_{i} \\ via\_cost = \sqrt{L} {\sum }_{i ∈ P} {y}_{tree} ( i ) {x}_{i} {TP}_{i} \\ overflow\_cost = {\sum }_{c ∈ E} f ( {cap}_{e} - {d}_{e} ) \\ {\sum }_{i : subnet ( i ) = s} {x}_{i} = 1 , ∀ s ∈ S \qquad Constraint 1$$

$${\sum }_{j : net ( j ) = n} {y}_{j} = 1 , ∀ n ∈ N \qquad Constraint 2$$

In this configuration, the settings a₁, a₂ and a₃ are weights applied to wire length cost, via cost, and overflow cost, respectively. WLᵢ is the wire length of the 2-pin path candidate i, and TPᵢ is the number of turning points of i. L is the number of routable layers in the circuit implementation. The element f represents a non-linear operator applied to the resource (capacity-demand) of the grid cell edges. Operators that may be utilized for f include ReLU, sigmoid, LeakyReLu, and CELU. Setting Constraint 1 ensures the selection of a single path for each 2-pin sub-net. Setting Constraint 2 ensures the selection of a single routing tree for each net.

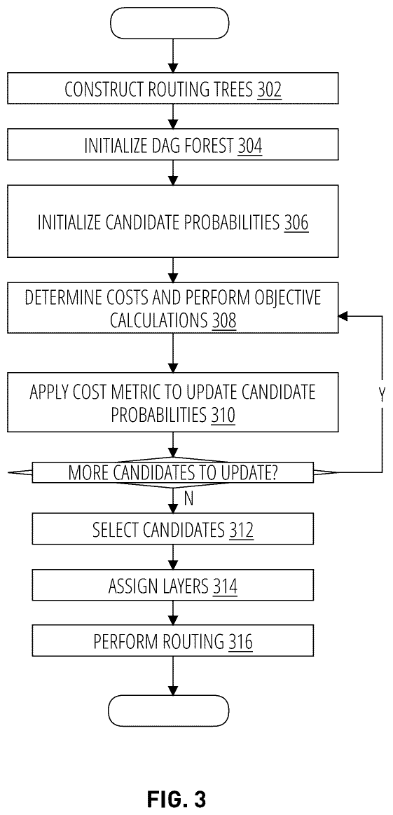

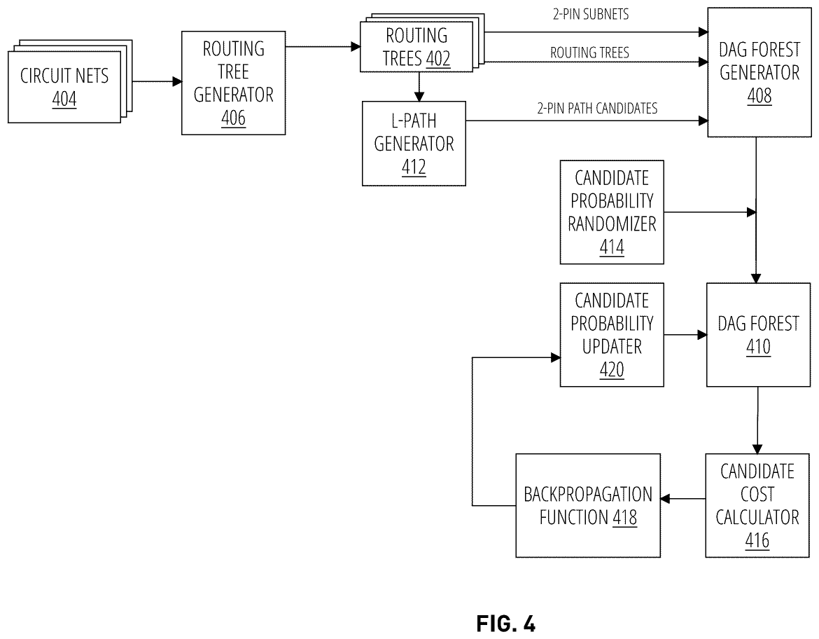

At a high-level, the differentiable global router may operate according to the process depicted in FIG. 3.

Routing trees 402 for the circuit nets 404 are constructed (302, routing tree generator 406) and structured (DAG forest generator 408) into a DAG forest 410 (304) that comprises a two-level hierarchy: a routing tree candidate pool and a 2-pin path candidate pool. The routing DAG forest 410 comprises routing tree candidates for each net, with each of these tree candidates spawning a collection of 2-pin path candidates. The routing tree candidate pool may be generated using conventional circuit design tools. In one embodiment, L-shape topology patterns (L-path generator 412) are applied to generate the 2-pin path candidate pool. An example of the constructed DAG forest is provided in FIG. 2.

Initially, multiple routing tree candidates are formulated for each net in the circuit (e.g., using conventional design tools). Subsequently, each routing tree for a net is applied to segment the multi-pin net into 2-pin segments based on its tree topology. The path patterns (e.g., L-shape path patterns) are enumerated for each 2-pin sub-net and incorporated into the pool as 2-pin path candidate.

The candidates are each associated with a selection probability (306, candidate probability randomizer 414) and costs are derived from these probabilities for performing the objective calculations (308, candidate cost calculator 416). The probabilities assigned to candidates may in one embodiment be initialized randomly (candidate probability randomizer 414).

Let (xᵢ, yⱼ) represent a path candidate and routing tree topology candidate. In order to make the search space for the differentiable solver continuous, define pᵢ∈[0, 1] as the probability of selecting 2-pin path candidate i, and qⱼ∈[0, 1] as the probability of selecting the routing tree topology candidate j. The cost metrics for the objective of the differentiable solver may be configured as:

$$WL\_cost = {\sum }_{i ∈ P} {q}_{tree} ( i ) {p}_{i} {WL}_{i} \\ via\_cost = \sqrt{L} {\sum }_{i ∈ P} {q}_{tree} ( i ) {p}_{i} {TP}_{i} \\ overflow\_cost = {\sum }_{e ∈ E} f ( {cap}_{e} - {d}_{e} ) \\ {d}_{e} = {\sum }_{i ∈ {P}_{e}} {q}_{tree} ( i ) {p}_{i} + {β}_{v} ( {\sum }_{k ∈ {P}_{v}} {q}_{tree} ( k ) {p}_{k} )$$

The total routing cost for a particular 2-pin path candidate i may be determined by a weighted sum of the overflow cost, wirelength cost, and via cost metrics above. The particular weight values may be determined experimentally or via simulation or both. One example of the metric weights is: total cost=500×overflow_cost+4×via_cost+0.5×wirelength_cost.

It may prove impractical to directly optimize the total cost function above due to the constraints of probabilities, in particular the constraints:

$${\sum }_{i : subnet ( i ) = s} {p}_{i} = 1 , ∀ s ∈ S ; ∀ {p}_{i} ∈ [ 0 , 1 ] \\ {\sum }_{j : net ( j ) = n} {q}_{j} = 1 , ∀ n ∈ N ; ∀ {q}_{i} ∈ [ 0 , 1 ]$$

To transform the constrained optimization problem for the differentiable solver into an unconstrained problem, an auxiliary model layer may be added to map unconstrained trainable variables (w={wᵢ∈ [symbol] }) to probabilities. In one embodiment this mapping may be implemented using a Softmax layer such as:

$${p}_{i} = \frac{exp ( {w}_{i} )}{{\sum }_{k : tree ( k ) = tree ( i )} exp ( {w}_{k} )} \\ {q}_{i} = \frac{exp ( {w}_{j} )}{{\sum }_{k : net ( k ) = net ( i )} exp ( {w}_{k} )}$$

A Softmax layer is commonly used in neural networks, particularly for classification tasks. It converts a vector of raw score values (logits) into probabilities that sum to one. Here is a step-by-step explanation of how it works:

The Softmax layer receives an input vector of logits from the previous layer in the network. These logits may be any real numbers. Each element in the input vector is exponentiated to ensure all values are positive and emphasize larger logits. The exponentiated values are then normalized by dividing each one by the sum of all exponentiated values in the vector. This step ensures the output probabilities sum to one. The resulting output of the Softmax layer is a probability distribution where each element's value lies between 0 and 1, and the total sum of all elements sums to 1.

However, a generic Softmax operator deterministically samples a probability distribution. This deterministic nature may inadvertently settle on local optima, for example when the probabilities are assigned certain initialization values. To address this possibility, a Gumbel Softmax operation may be implemented in the auxiliary layer as follows:

$${p}_{i} = \frac{exp ( \frac{( {w}_{i} + {g}_{i} )}{t} )}{{\sum }_{k : tree ( k ) = tree ( i )} exp ( \frac{( {w}_{k} + {g}_{k} )}{t} )} \\ {q}_{j} = \frac{exp ( \frac{( {w}_{j} + {g}_{j} )}{t} )}{{\sum }_{k : net ( k ) = net ( j )} exp ( \frac{( {w}_{k} + {g}_{k} )}{t} )}$$

This stochastic variant of Softmax introduces Gumbel noise gi sampled from a Gumbel distribution to the logit terms wᵢ, wₖ of the Softmax. A “temperature” parameter t is also introduced into the auxiliary layer operator to ensure discrete sampling of the routing tree candidates. The temperature parameter t may be progressively reduced during iterations on the candidates. These features may help ensure that the probabilities associated with routing tree candidates converge toward either 0 or 1 after sufficient iterations.

The parameter t may be utilized to introduce temperature annealing effects into the selection process. Temperature annealing is a heat treatment process used to alter the physical properties of a material to increase its ductility and reduce its hardness, thereby making it more workable. The process involves heating the material to a specific temperature, holding it at that temperature for a designated period, and then cooling it at a controlled rate.

The computed total cost metric for candidate routes is back-propagated to the candidate pool (310, backpropagation function 418), e.g., using a gradient descent, to update each candidate's probability (candidate probability updater 420), e.g., based on the cost distances from the minimum determined candidate cost for each net.

Candidate costs may be computed as a differentiable function of the candidate probabilities. The gradient of the cost with respect to the probability may be calculated, followed by updating the probability using gradient descent.

This cycle continues until an iteration limit or quality score is satisfied. Once the update cycles complete, candidates are selected from the candidate pool based on the refined probabilities (312). For routing tree candidates, the candidate with the highest probability may be chosen. This probability typically approaches a value of 1 as a consequence of the temperature parameter's gradual reduction over the iterations. Top-p sampling may be employed to select the 2-pin path candidate. Initially, candidates may be ranked by their probabilities and subsequently the top candidates are selected until their cumulative probability surpasses a predefined threshold setting.

Once routing tree topologies and routing path candidates are selected, routing layer assignments may be made (314), and the coarse-routing candidates may be provided as guidance to the detailed routing tool (316). For example, a directed acyclic graph may be constructed for each net based on the selected candidates and these DAGs and layer assignments may be input to a coarse-grained three-dimensional circuit routing tool. The layer assignments may yield preliminary 3D routes. Subsequent iterations of the 3D routing tool may refine these 3D routes to further reduce any overflow. The final results of the 3D routing tool comprise a comprehensive guide for use by a detailed (fine-grained) circuit router.

The mechanisms disclosed herein may be efficiently implemented on computing devices utilizing one or more graphic processing unit (GPU) and/or general purpose data processor (e.g., a central processing unit—CPU). Exemplary architectures will now be described that may be configured to implement the mechanisms disclosed herein on such devices.

The following description may use certain acronyms and abbreviations as follows:
“DPC” refers to a “data processing cluster”;
“GPC” refers to a “general processing cluster”;
“I/O” refers to a “input/output”;
“L1 cache” refers to “level one cache”;
“L2 cache” refers to “level two cache”;
“LSU” refers to a “load/store unit”;
“MMU” refers to a “memory management unit”;
“MPC” refers to an “M-pipe controller”;
“PPU” refers to a “parallel processing unit”;
“PROP” refers to a “pre-raster operations unit”;
“ROP” refers to a “raster operations”;
“SFU” refers to a “special function unit”;
“SM” refers to a “streaming multiprocessor”;
“Viewport SCC” refers to “viewport scale, cull, and clip”;
“WDX” refers to a “work distribution crossbar”; and
“XBar” refers to a “crossbar”.

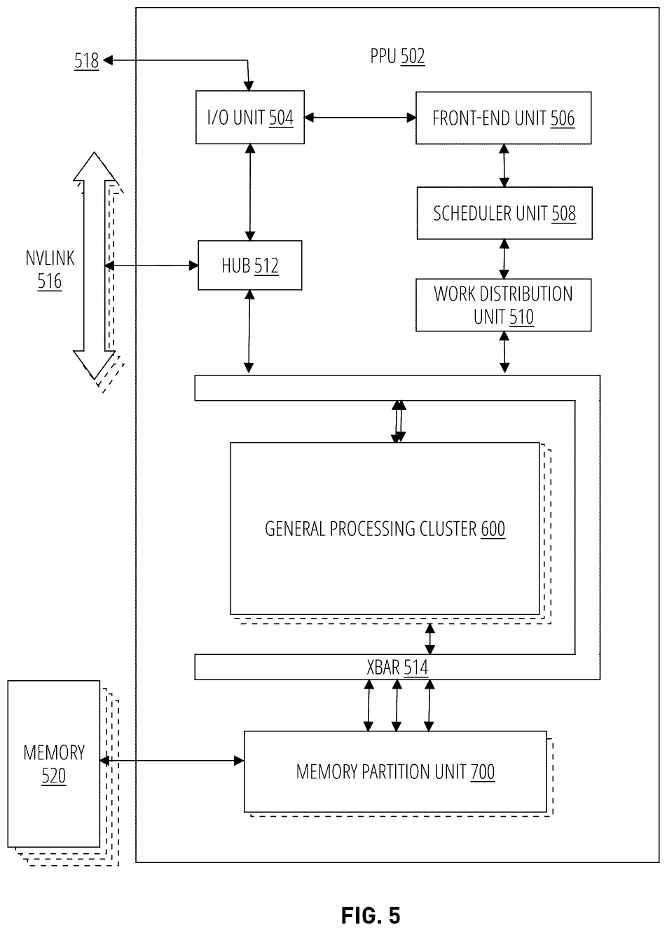

FIG. 5 depicts a parallel processing unit 502, in accordance with an embodiment. In an embodiment, the parallel processing unit 502 is a multi-threaded processor that is implemented on one or more integrated circuit devices. The parallel processing unit 502 is a latency hiding architecture designed to process many threads in parallel. A thread (e.g., a thread of execution) is an instantiation of a set of instructions configured to be executed by the parallel processing unit 502. In an embodiment, the parallel processing unit 502 is a graphics processing unit (GPU) configured to implement a graphics rendering pipeline for processing three-dimensional (3D) graphics data in order to generate two-dimensional (2D) image data for display on a display device such as a liquid crystal display (LCD) device. In other embodiments, the parallel processing unit 502 may be utilized for performing general-purpose computations. While one exemplary parallel processor is provided herein for illustrative purposes, it should be strongly noted that such processor is set forth for illustrative purposes only, and that any processor may be employed to supplement and/or substitute for the same.

One or more parallel processing unit 502 modules may be configured to accelerate thousands of High Performance Computing (HPC), data center, and machine learning applications. The parallel processing unit 502 may be configured to accelerate numerous deep learning systems and applications including autonomous vehicle platforms, deep learning, high-accuracy speech, image, and text recognition systems, intelligent video analytics, molecular simulations, drug discovery, disease diagnosis, weather forecasting, big data analytics, astronomy, molecular dynamics simulation, financial modeling, robotics, factory automation, real-time language translation, online search optimizations, and personalized user recommendations, and the like.

As shown in FIG. 5, the parallel processing unit 502 includes an I/O unit 504, a front-end unit 506, a scheduler unit 508, a work distribution unit 510, a hub 512, a crossbar 514, one or more general processing cluster 600 modules, and one or more memory partition unit 700 modules. The parallel processing unit 502 may be connected to a host processor or other parallel processing unit 502 modules via one or more high-speed NVLink 516 interconnects. The parallel processing unit 502 may be connected to a host processor or other peripheral devices via an interconnect 518. The parallel processing unit 502 may also be connected to a local memory comprising a number of memory 520 devices. In an embodiment, the local memory may comprise a number of dynamic random access memory (DRAM) devices. The DRAM devices may be configured as a high-bandwidth memory (HBM) subsystem, with multiple DRAM dies stacked within each device. The memory 520 may comprise logic to configure the parallel processing unit 502 to carry out aspects of the techniques disclosed herein.

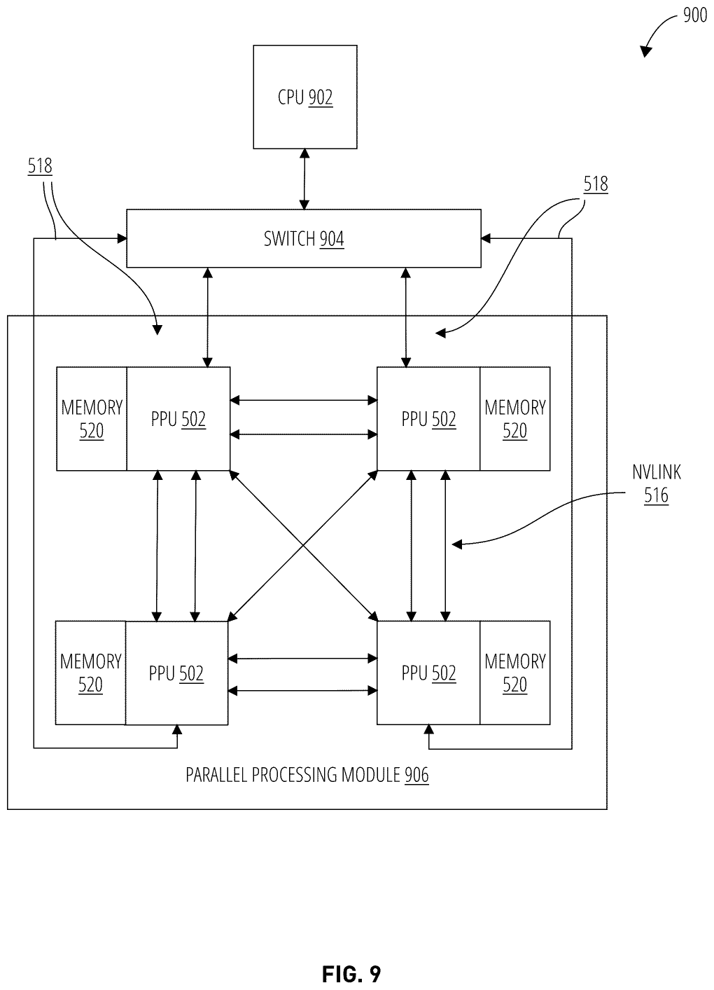

The NVLink 516 interconnect enables systems to scale and include one or more parallel processing unit 502 modules combined with one or more CPUs, supports cache coherence between the parallel processing unit 502 modules and CPUs, and CPU mastering. Data and/or commands may be transmitted by the NVLink 516 through the hub 512 to/from other units of the parallel processing unit 502 such as one or more copy engines, a video encoder, a video decoder, a power management unit, etc. (not explicitly shown). The NVLink 516 is described in more detail in conjunction with FIG. 9.

The I/O unit 504 is configured to transmit and receive communications (e.g., commands, data, etc.) from a host processor (not shown) over the interconnect 518. The I/O unit 504 may communicate with the host processor directly via the interconnect 518 or through one or more intermediate devices such as a memory bridge. In an embodiment, the I/O unit 504 may communicate with one or more other processors, such as one or more parallel processing unit 502 modules via the interconnect 518. In an embodiment, the I/O unit 504 implements a Peripheral Component Interconnect Express (PCIe) interface for communications over a PCIe bus and the interconnect 518 is a PCIe bus. In alternative embodiments, the I/O unit 504 may implement other types of well-known interfaces for communicating with external devices.

The I/O unit 504 decodes packets received via the interconnect 518. In an embodiment, the packets represent commands configured to cause the parallel processing unit 502 to perform various operations. The I/O unit 504 transmits the decoded commands to various other units of the parallel processing unit 502 as the commands may specify. For example, some commands may be transmitted to the front-end unit 506. Other commands may be transmitted to the hub 512 or other units of the parallel processing unit 502 such as one or more copy engines, a video encoder, a video decoder, a power management unit, etc. (not explicitly shown). In other words, the I/O unit 504 is configured to route communications between and among the various logical units of the parallel processing unit 502.

In an embodiment, a program executed by the host processor encodes a command stream in a buffer that provides workloads to the parallel processing unit 502 for processing. A workload may comprise several instructions and data to be processed by those instructions. The buffer is a region in a memory that is accessible (e.g., read/write) by both the host processor and the parallel processing unit 502. For example, the I/O unit 504 may be configured to access the buffer in a system memory connected to the interconnect 518 via memory requests transmitted over the interconnect 518. In an embodiment, the host processor writes the command stream to the buffer and then transmits a pointer to the start of the command stream to the parallel processing unit 502. The front-end unit 506 receives pointers to one or more command streams. The front-end unit 506 manages the one or more streams, reading commands from the streams and forwarding commands to the various units of the parallel processing unit 502.

The front-end unit 506 is coupled to a scheduler unit 508 that configures the various general processing cluster 600 modules to process tasks defined by the one or more streams. The scheduler unit 508 is configured to track state information related to the various tasks managed by the scheduler unit 508. The state may indicate which general processing cluster 600 a task is assigned to, whether the task is active or inactive, a priority level associated with the task, and so forth. The scheduler unit 508 manages the execution of a plurality of tasks on the one or more general processing cluster 600 modules.

The scheduler unit 508 is coupled to a work distribution unit 510 that is configured to dispatch tasks for execution on the general processing cluster 600 modules. The work distribution unit 510 may track a number of scheduled tasks received from the scheduler unit 508. In an embodiment, the work distribution unit 510 manages a pending task pool and an active task pool for each of the general processing cluster 600 modules. The pending task pool may comprise a number of slots (e.g., 32 slots) that contain tasks assigned to be processed by a particular general processing cluster 600. The active task pool may comprise a number of slots (e.g., 4 slots) for tasks that are actively being processed by the general processing cluster 600 modules. As a general processing cluster 600 finishes the execution of a task, that task is evicted from the active task pool for the general processing cluster 600 and one of the other tasks from the pending task pool is selected and scheduled for execution on the general processing cluster 600. If an active task has been idle on the general processing cluster 600, such as while waiting for a data dependency to be resolved, then the active task may be evicted from the general processing cluster 600 and returned to the pending task pool while another task in the pending task pool is selected and scheduled for execution on the general processing cluster 600.

The work distribution unit 510 communicates with the one or more general processing cluster 600 modules via crossbar 514. The crossbar 514 is an interconnect network that couples many of the units of the parallel processing unit 502 to other units of the parallel processing unit 502. For example, the crossbar 514 may be configured to couple the work distribution unit 510 to a particular general processing cluster 600. Although not shown explicitly, one or more other units of the parallel processing unit 502 may also be connected to the crossbar 514 via the hub 512.

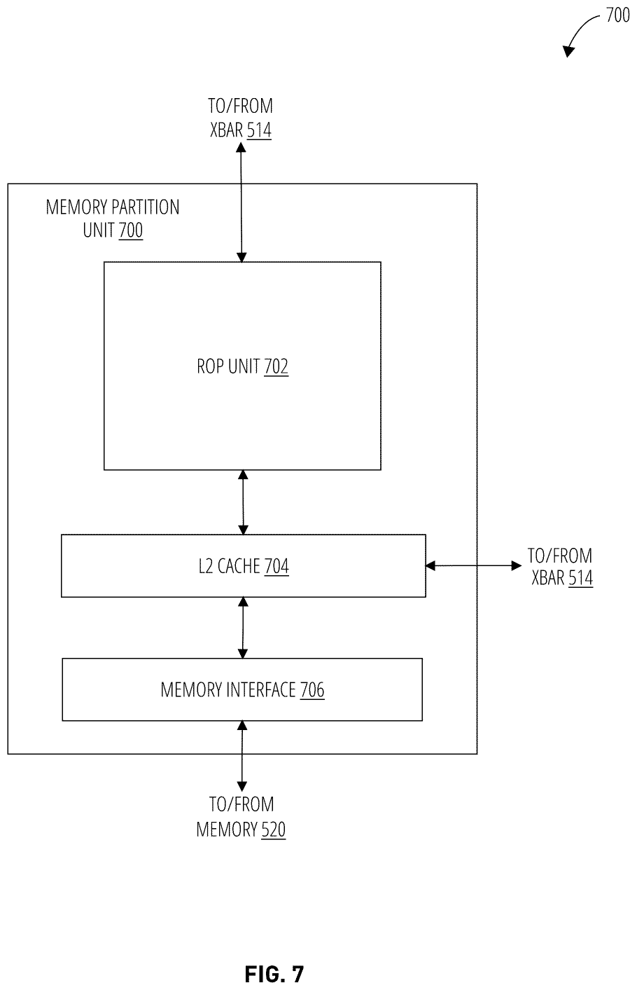

The tasks are managed by the scheduler unit 508 and dispatched to a general processing cluster 600 by the work distribution unit 510. The general processing cluster 600 is configured to process the task and generate results. The results may be consumed by other tasks within the general processing cluster 600, routed to a different general processing cluster 600 via the crossbar 514, or stored in the memory 520. The results can be written to the memory 520 via the memory partition unit 700 modules, which implement a memory interface for reading and writing data to/from the memory 520. The results can be transmitted to another parallel processing unit 502 or CPU via the NVLink 516. In an embodiment, the parallel processing unit 502 includes a number U of memory partition unit 700 modules that is equal to the number of separate and distinct memory 520 devices coupled to the parallel processing unit 502. A memory partition unit 700 will be described in more detail below in conjunction with FIG. 7.

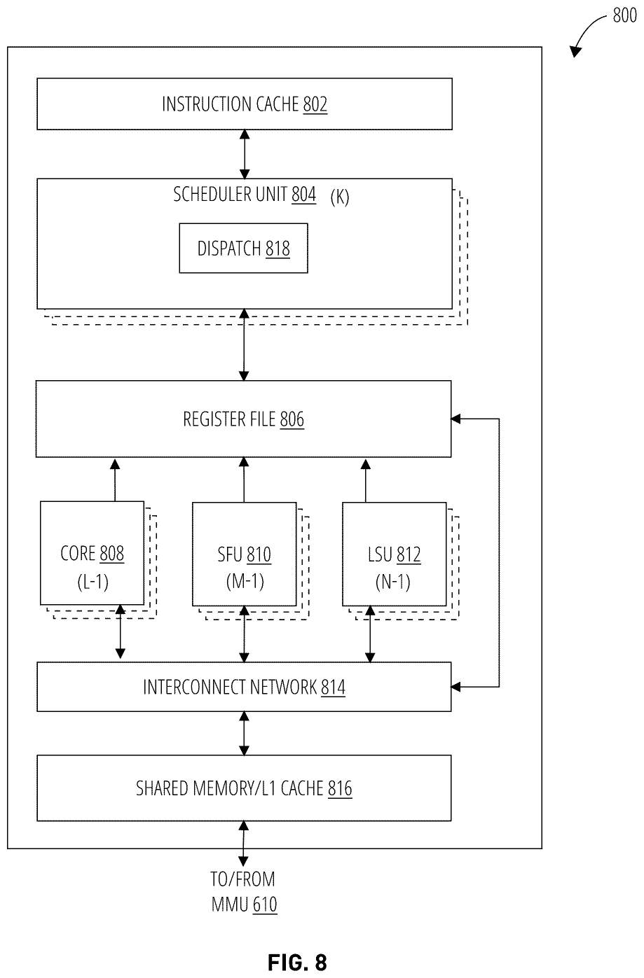

In an embodiment, a host processor executes a driver kernel that implements an application programming interface (API) that enables one or more applications executing on the host processor to schedule operations for execution on the parallel processing unit 502. In an embodiment, multiple compute applications are simultaneously executed by the parallel processing unit 502 and the parallel processing unit 502 provides isolation, quality of service (QoS), and independent address spaces for the multiple compute applications. An application may generate instructions (e.g., API calls) that cause the driver kernel to generate one or more tasks for execution by the parallel processing unit 502. The driver kernel outputs tasks to one or more streams being processed by the parallel processing unit 502. Each task may comprise one or more groups of related threads, referred to herein as a warp. In an embodiment, a warp comprises 32 related threads that may be executed in parallel. Cooperating threads may refer to a plurality of threads including instructions to perform the task and that may exchange data through shared memory. Threads and cooperating threads are described in more detail in conjunction with FIG. 8.

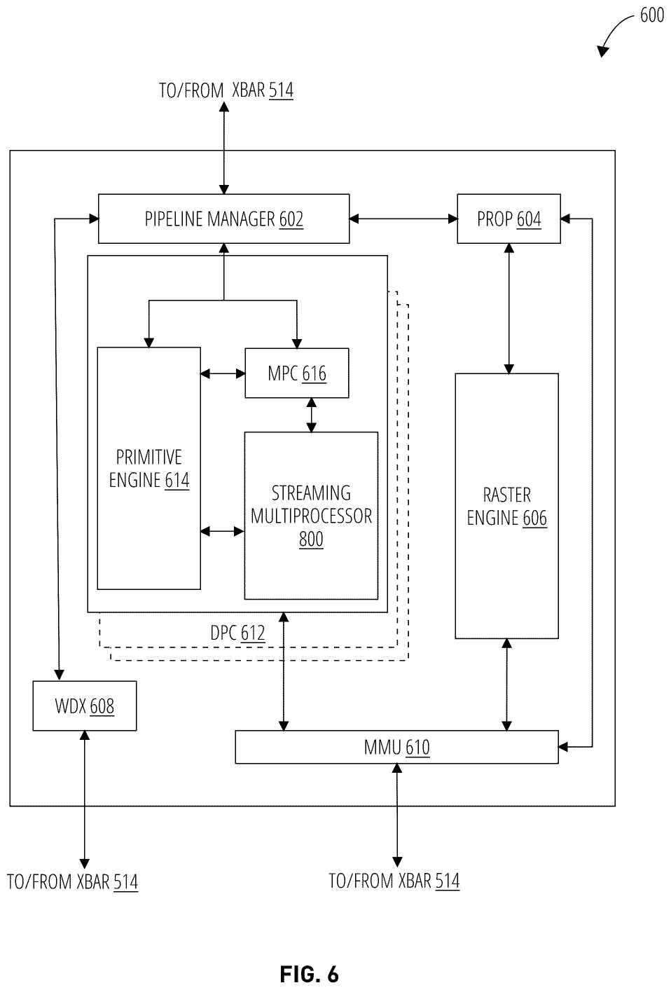

FIG. 6 depicts a general processing cluster 600 of the parallel processing unit 502 of FIG. 5, in accordance with an embodiment. As shown in FIG. 6, each general processing cluster 600 includes a number of hardware units for processing tasks. In an embodiment, each general processing cluster 600 includes a pipeline manager 602, a pre-raster operations unit 604, a raster engine 606, a work distribution crossbar 608, a memory management unit 610, and one or more data processing cluster 612. It will be appreciated that the general processing cluster 600 of FIG. 6 may include other hardware units in lieu of or in addition to the units shown in FIG. 6.

In an embodiment, the operation of the general processing cluster 600 is controlled by the pipeline manager 602. The pipeline manager 602 manages the configuration of the one or more data processing cluster 612 modules for processing tasks allocated to the general processing cluster 600. In an embodiment, the pipeline manager 602 may configure at least one of the one or more data processing cluster 612 modules to implement at least a portion of a graphics rendering pipeline. For example, a data processing cluster 612 may be configured to execute a vertex shader program on the programmable streaming multiprocessor 800. The pipeline manager 602 may also be configured to route packets received from the work distribution unit 510 to the appropriate logical units within the general processing cluster 600. For example, some packets may be routed to fixed function hardware units in the pre-raster operations unit 604 and/or raster engine 606 while other packets may be routed to the data processing cluster 612 modules for processing by the primitive engine 614 or the streaming multiprocessor 800. In an embodiment, the pipeline manager 602 may configure at least one of the one or more data processing cluster 612 modules to implement a neural network model and/or a computing pipeline.

The pre-raster operations unit 604 is configured to route data generated by the raster engine 606 and the data processing cluster 612 modules to a Raster Operations (ROP) unit, described in more detail in conjunction with FIG. 7. The pre-raster operations unit 604 may also be configured to perform optimizations for color blending, organize pixel data, perform address translations, and the like.

The raster engine 606 includes a number of fixed function hardware units configured to perform various raster operations. In an embodiment, the raster engine 606 includes a setup engine, a coarse raster engine, a culling engine, a clipping engine, a fine raster engine, and a tile coalescing engine. The setup engine receives transformed vertices and generates plane equations associated with the geometric primitive defined by the vertices. The plane equations are transmitted to the coarse raster engine to generate coverage information (e.g., an x, y coverage mask for a tile) for the primitive. The output of the coarse raster engine is transmitted to the culling engine where fragments associated with the primitive that fail a z-test are culled, and transmitted to a clipping engine where fragments lying outside a viewing frustum are clipped. Those fragments that survive clipping and culling may be passed to the fine raster engine to generate attributes for the pixel fragments based on the plane equations generated by the setup engine. The output of the raster engine 606 comprises fragments to be processed, for example, by a fragment shader implemented within a data processing cluster 612.

Each data processing cluster 612 included in the general processing cluster 600 includes an M-pipe controller 616, a primitive engine 614, and one or more streaming multiprocessor 800 modules. The M-pipe controller 616 controls the operation of the data processing cluster 612, routing packets received from the pipeline manager 602 to the appropriate units in the data processing cluster 612. For example, packets associated with a vertex may be routed to the primitive engine 614, which is configured to fetch vertex attributes associated with the vertex from the memory 520. In contrast, packets associated with a shader program may be transmitted to the streaming multiprocessor 800.

The streaming multiprocessor 800 comprises a programmable streaming processor that is configured to process tasks represented by a number of threads. Each streaming multiprocessor 800 is multi-threaded and configured to execute a plurality of threads (e.g., 32 threads) from a particular group of threads concurrently. In an embodiment, the streaming multiprocessor 800 implements a Single-Instruction, Multiple-Data (SIMD) architecture where each thread in a group of threads (e.g., a warp) is configured to process a different set of data based on the same set of instructions. All threads in the group of threads execute the same instructions. In another embodiment, the streaming multiprocessor 800 implements a Single-Instruction, Multiple Thread (SIMT) architecture where each thread in a group of threads is configured to process a different set of data based on the same set of instructions, but where individual threads in the group of threads are allowed to diverge during execution. In an embodiment, a program counter, call stack, and execution state is maintained for each warp, enabling concurrency between warps and serial execution within warps when threads within the warp diverge. In another embodiment, a program counter, call stack, and execution state is maintained for each individual thread, enabling equal concurrency between all threads, within and between warps. When execution state is maintained for each individual thread, threads executing the same instructions may be converged and executed in parallel for maximum efficiency. The streaming multiprocessor 800 will be described in more detail below in conjunction with FIG. 8.

The memory management unit 610 provides an interface between the general processing cluster 600 and the memory partition unit 700. The memory management unit 610 may provide translation of virtual addresses into physical addresses, memory protection, and arbitration of memory requests. In an embodiment, the memory management unit 610 provides one or more translation lookaside buffers (TLBs) for performing translation of virtual addresses into physical addresses in the memory 520.

FIG. 7 depicts a memory partition unit 700 of the parallel processing unit 502 of FIG. 5, in accordance with an embodiment. As shown in FIG. 7, the memory partition unit 700 includes a raster operations unit 702, a level two cache 704, and a memory interface 706. The memory interface 706 is coupled to the memory 520. Memory interface 706 may implement 32, 64, 128, 1024-bit data buses, or the like, for high-speed data transfer. In an embodiment, the parallel processing unit 502 incorporates U memory interface 706 modules, one memory interface 706 per pair of memory partition unit 700 modules, where each pair of memory partition unit 700 modules is connected to a corresponding memory 520 device. For example, parallel processing unit 502 may be connected to up to Y memory 520 devices, such as high bandwidth memory stacks or graphics double-data-rate, version 5, synchronous dynamic random access memory, or other types of persistent storage.

In an embodiment, the memory interface 706 implements an HBM2 memory interface and Y equals half U. In an embodiment, the HBM2 memory stacks are located on the same physical package as the parallel processing unit 502, providing substantial power and area savings compared with conventional GDDR5 SDRAM systems. In an embodiment, each HBM2 stack includes four memory dies and Y equals 4, with HBM2 stack including two 128-bit channels per die for a total of 8 channels and a data bus width of 1024 bits.

In an embodiment, the memory 520 supports Single-Error Correcting Double-Error Detecting (SECDED) Error Correction Code (ECC) to protect data. ECC provides higher reliability for compute applications that are sensitive to data corruption. Reliability is especially important in large-scale cluster computing environments where parallel processing unit 502 modules process very large datasets and/or run applications for extended periods.

In an embodiment, the parallel processing unit 502 implements a multi-level memory hierarchy. In an embodiment, the memory partition unit 700 supports a unified memory to provide a single unified virtual address space for CPU and parallel processing unit 502 memory, enabling data sharing between virtual memory systems. In an embodiment the frequency of accesses by a parallel processing unit 502 to memory located on other processors is traced to ensure that memory pages are moved to the physical memory of the parallel processing unit 502 that is accessing the pages more frequently. In an embodiment, the NVLink 516 supports address translation services allowing the parallel processing unit 502 to directly access a CPU's page tables and providing full access to CPU memory by the parallel processing unit 502.

In an embodiment, copy engines transfer data between multiple parallel processing unit 502 modules or between parallel processing unit 502 modules and CPUs. The copy engines can generate page faults for addresses that are not mapped into the page tables. The memory partition unit 700 can then service the page faults, mapping the addresses into the page table, after which the copy engine can perform the transfer. In a conventional system, memory is pinned (e.g., non-pageable) for multiple copy engine operations between multiple processors, substantially reducing the available memory. With hardware page faulting, addresses can be passed to the copy engines without worrying if the memory pages are resident, and the copy process is transparent.

Data from the memory 520 or other system memory may be fetched by the memory partition unit 700 and stored in the level two cache 704, which is located on-chip and is shared between the various general processing cluster 600 modules. As shown, each memory partition unit 700 includes a portion of the level two cache 704 associated with a corresponding memory 520 device. Lower level caches may then be implemented in various units within the general processing cluster 600 modules. For example, each of the streaming multiprocessor 800 modules may implement an L1 cache. The L1 cache is private memory that is dedicated to a particular streaming multiprocessor 800. Data from the level two cache 704 may be fetched and stored in each of the L1 caches for processing in the functional units of the streaming multiprocessor 800 modules. The level two cache 704 is coupled to the memory interface 706 and the crossbar 514.

The raster operations unit 702 performs graphics raster operations related to pixel color, such as color compression, pixel blending, and the like. The raster operations unit 702 also implements depth testing in conjunction with the raster engine 606, receiving a depth for a sample location associated with a pixel fragment from the culling engine of the raster engine 606. The depth is tested against a corresponding depth in a depth buffer for a sample location associated with the fragment. If the fragment passes the depth test for the sample location, then the raster operations unit 702 updates the depth buffer and transmits a result of the depth test to the raster engine 606. It will be appreciated that the number of partition memory partition unit 700 modules may be different than the number of general processing cluster 600 modules and, therefore, each raster operations unit 702 may be coupled to each of the general processing cluster 600 modules. The raster operations unit 702 tracks packets received from the different general processing cluster 600 modules and determines which general processing cluster 600 that a result generated by the raster operations unit 702 is routed to through the crossbar 514. Although the raster operations unit 702 is included within the memory partition unit 700 in FIG. 7, in other embodiment, the raster operations unit 702 may be outside of the memory partition unit 700. For example, the raster operations unit 702 may reside in the general processing cluster 600 or another unit.

FIG. 8 illustrates the streaming multiprocessor 800 of FIG. 6, in accordance with an embodiment. As shown in FIG. 8, the streaming multiprocessor 800 includes an instruction cache 802, one or more scheduler unit 804 modules (e.g., such as scheduler unit 508), a register file 806, one or more processing core 808 modules, one or more special function unit 810 modules, one or more load/store unit 812 modules, an interconnect network 814, and a shared memory/L1 cache 816.

As described above, the work distribution unit 510 dispatches tasks for execution on the general processing cluster 600 modules of the parallel processing unit 502. The tasks are allocated to a particular data processing cluster 612 within a general processing cluster 600 and, if the task is associated with a shader program, the task may be allocated to a streaming multiprocessor 800. The scheduler unit 508 receives the tasks from the work distribution unit 510 and manages instruction scheduling for one or more thread blocks assigned to the streaming multiprocessor 800. The scheduler unit 804 schedules thread blocks for execution as warps of parallel threads, where each thread block is allocated at least one warp. In an embodiment, each warp executes 32 threads. The scheduler unit 804 may manage a plurality of different thread blocks, allocating the warps to the different thread blocks and then dispatching instructions from the plurality of different cooperative groups to the various functional units (e.g., core 808 modules, special function unit 810 modules, and load/store unit 812 modules) during each clock cycle.

Cooperative Groups is a programming model for organizing groups of communicating threads that allows developers to express the granularity at which threads are communicating, enabling the expression of richer, more efficient parallel decompositions. Cooperative launch APIs support synchronization amongst thread blocks for the execution of parallel algorithms. Conventional programming models provide a single, simple construct for synchronizing cooperating threads: a barrier across all threads of a thread block (e.g., the syncthreads( ) function). However, programmers would often like to define groups of threads at smaller than thread block granularities and synchronize within the defined groups to enable greater performance, design flexibility, and software reuse in the form of collective group-wide function interfaces.

Cooperative Groups enables programmers to define groups of threads explicitly at sub-block (e.g., as small as a single thread) and multi-block granularities, and to perform collective operations such as synchronization on the threads in a cooperative group. The programming model supports clean composition across software boundaries, so that libraries and utility functions can synchronize safely within their local context without having to make assumptions about convergence. Cooperative Groups primitives enable new patterns of cooperative parallelism, including producer-consumer parallelism, opportunistic parallelism, and global synchronization across an entire grid of thread blocks.

A dispatch 818 unit is configured within the scheduler unit 804 to transmit instructions to one or more of the functional units. In one embodiment, the scheduler unit 804 includes two dispatch 818 units that enable two different instructions from the same warp to be dispatched during each clock cycle. In alternative embodiments, each scheduler unit 804 may include a single dispatch 818 unit or additional dispatch 818 units.

Each streaming multiprocessor 800 includes a register file 806 that provides a set of registers for the functional units of the streaming multiprocessor 800. In an embodiment, the register file 806 is divided between each of the functional units such that each functional unit is allocated a dedicated portion of the register file 806. In another embodiment, the register file 806 is divided between the different warps being executed by the streaming multiprocessor 800. The register file 806 provides temporary storage for operands connected to the data paths of the functional units.

Each streaming multiprocessor 800 comprises L processing core 808 modules. In an embodiment, the streaming multiprocessor 800 includes a large number (e.g., 128, etc.) of distinct processing core 808 modules. Each core 808 may include a fully-pipelined, single-precision, double-precision, and/or mixed precision processing unit that includes a floating point arithmetic logic unit and an integer arithmetic logic unit. In an embodiment, the floating point arithmetic logic units implement the IEEE 754-2008 standard for floating point arithmetic. In an embodiment, the core 808 modules include 64 single-precision (32-bit) floating point cores, 64 integer cores, 32 double-precision (64-bit) floating point cores, and 8 tensor cores.

Tensor cores configured to perform matrix operations, and, in an embodiment, one or more tensor cores are included in the core 808 modules. In particular, the tensor cores are configured to perform deep learning matrix arithmetic, such as convolution operations for neural network training and inferencing. In an embodiment, each tensor core operates on a 4×4 matrix and performs a matrix multiply and accumulate operation D=A′B+C, where A, B, C, and D are 4×4 matrices.

In an embodiment, the matrix multiply inputs A and B are 16-bit floating point matrices, while the accumulation matrices C and D may be 16-bit floating point or 32-bit floating point matrices. Tensor Cores operate on 16-bit floating point input data with 32-bit floating point accumulation. The 16-bit floating point multiply requires 64 operations and results in a full precision product that is then accumulated using 32-bit floating point addition with the other intermediate products for a 4×4×4 matrix multiply. In practice, Tensor Cores are used to perform much larger two-dimensional or higher dimensional matrix operations, built up from these smaller elements. An API, such as CUDA 9 C++ API, exposes specialized matrix load, matrix multiply and accumulate, and matrix store operations to efficiently use Tensor Cores from a CUDA-C++ program. At the CUDA level, the warp-level interface assumes 16×16 size matrices spanning all 32 threads of the warp.

Each streaming multiprocessor 800 also comprises M special function unit 810 modules that perform special functions (e.g., attribute evaluation, reciprocal square root, and the like). In an embodiment, the special function unit 810 modules may include a tree traversal unit configured to traverse a hierarchical tree data structure. In an embodiment, the special function unit 810 modules may include texture unit configured to perform texture map filtering operations. In an embodiment, the texture units are configured to load texture maps (e.g., a 2D array of texels) from the memory 520 and sample the texture maps to produce sampled texture values for use in shader programs executed by the streaming multiprocessor 800. In an embodiment, the texture maps are stored in the shared memory/L1 cache 816. The texture units implement texture operations such as filtering operations using mip-maps (e.g., texture maps of varying levels of detail). In an embodiment, each streaming multiprocessor 800 includes two texture units.

Each streaming multiprocessor 800 also comprises N load/store unit 812 modules that implement load and store operations between the shared memory/L1 cache 816 and the register file 806. Each streaming multiprocessor 800 includes an interconnect network 814 that connects each of the functional units to the register file 806 and the load/store unit 812 to the register file 806 and shared memory/L1 cache 816. In an embodiment, the interconnect network 814 is a crossbar that can be configured to connect any of the functional units to any of the registers in the register file 806 and connect the load/store unit 812 modules to the register file 806 and memory locations in shared memory/L1 cache 816.

The shared memory/L1 cache 816 is an array of on-chip memory that allows for data storage and communication between the streaming multiprocessor 800 and the primitive engine 614 and between threads in the streaming multiprocessor 800. In an embodiment, the shared memory/L1 cache 816 comprises 128 KB of storage capacity and is in the path from the streaming multiprocessor 800 to the memory partition unit 700. The shared memory/L1 cache 816 can be used to cache reads and writes. One or more of the shared memory/L1 cache 816, level two cache 704, and memory 520 are backing stores.

Combining data cache and shared memory functionality into a single memory block provides the best overall performance for both types of memory accesses. The capacity is usable as a cache by programs that do not use shared memory. For example, if shared memory is configured to use half of the capacity, texture and load/store operations can use the remaining capacity. Integration within the shared memory/L1 cache 816 enables the shared memory/L1 cache 816 to function as a high-throughput conduit for streaming data while simultaneously providing high-bandwidth and low-latency access to frequently reused data.

When configured for general purpose parallel computation, a simpler configuration can be used compared with graphics processing. Specifically, the fixed function graphics processing units shown in FIG. 5, are bypassed, creating a much simpler programming model. In the general purpose parallel computation configuration, the work distribution unit 510 assigns and distributes blocks of threads directly to the data processing cluster 612 modules. The threads in a block execute the same program, using a unique thread ID in the calculation to ensure each thread generates unique results, using the streaming multiprocessor 800 to execute the program and perform calculations, shared memory/L1 cache 816 to communicate between threads, and the load/store unit 812 to read and write global memory through the shared memory/L1 cache 816 and the memory partition unit 700. When configured for general purpose parallel computation, the streaming multiprocessor 800 can also write commands that the scheduler unit 508 can use to launch new work on the data processing cluster 612 modules.

The parallel processing unit 502 may be included in a desktop computer, a laptop computer, a tablet computer, servers, supercomputers, a smart-phone (e.g., a wireless, hand-held device), personal digital assistant (PDA), a digital camera, a vehicle, a head mounted display, a hand-held electronic device, and the like. In an embodiment, the parallel processing unit 502 is embodied on a single semiconductor substrate. In another embodiment, the parallel processing unit 502 is included in a system-on-a-chip (SoC) along with one or more other devices such as additional parallel processing unit 502 modules, the memory 520, a reduced instruction set computer (RISC) CPU, a memory management unit (MMU), a digital-to-analog converter (DAC), and the like.

In an embodiment, the parallel processing unit 502 may be included on a graphics card that includes one or more memory devices. The graphics card may be configured to interface with a PCIe slot on a motherboard of a desktop computer. In yet another embodiment, the parallel processing unit 502 may be an integrated graphics processing unit (iGPU) or parallel processor included in the chipset of the motherboard.

### Exemplary Computing System

Systems with multiple GPUs and CPUs are used in a variety of industries as developers expose and leverage more parallelism in applications such as artificial intelligence computing. High-performance GPU-accelerated systems with tens to many thousands of compute nodes are deployed in data centers, research facilities, and supercomputers to solve ever larger problems. As the number of processing devices within the high-performance systems increases, the communication and data transfer mechanisms need to scale to support the increased bandwidth.

FIG. 9 is a conceptual diagram of a processing system 900 implemented using the parallel processing unit 502 of FIG. 5, in accordance with an embodiment. The processing system 900 includes a central processing unit 902, switch 904, and multiple parallel processing unit 502 modules each and respective memory 520 modules. The NVLink 516 provides high-speed communication links between each of the parallel processing unit 502 modules. Although a particular number of NVLink 516 and interconnect 518 connections are illustrated in FIG. 9, the number of connections to each parallel processing unit 502 and the central processing unit 902 may vary. The switch 904 interfaces between the interconnect 518 and the central processing unit 902. The parallel processing unit 502 modules, memory 520 modules, and NVLink 516 connections may be situated on a single semiconductor platform to form a parallel processing module 906. In an embodiment, the switch 904 supports two or more protocols to interface between various different connections and/or links.

In another embodiment (not shown), the NVLink 516 provides one or more high-speed communication links between each of the parallel processing unit modules (parallel processing unit 502, parallel processing unit 502, parallel processing unit 502, and parallel processing unit 502) and the central processing unit 902 and the switch 904 interfaces between the interconnect 518 and each of the parallel processing unit modules. The parallel processing unit modules, memory 520 modules, and interconnect 518 may be situated on a single semiconductor platform to form a parallel processing module 906. In yet another embodiment (not shown), the interconnect 518 provides one or more communication links between each of the parallel processing unit modules and the central processing unit 902 and the switch 904 interfaces between each of the parallel processing unit modules using the NVLink 516 to provide one or more high-speed communication links between the parallel processing unit modules. In another embodiment (not shown), the NVLink 516 provides one or more high-speed communication links between the parallel processing unit modules and the central processing unit 902 through the switch 904. In yet another embodiment (not shown), the interconnect 518 provides one or more communication links between each of the parallel processing unit modules directly. One or more of the NVLink 516 high-speed communication links may be implemented as a physical NVLink interconnect or either an on-chip or on-die interconnect using the same protocol as the NVLink 516.

In the context of the present description, a single semiconductor platform may refer to a sole unitary semiconductor-based integrated circuit fabricated on a die or chip. It should be noted that the term single semiconductor platform may also refer to multi-chip modules with increased connectivity which simulate on-chip operation and make substantial improvements over utilizing a conventional bus implementation. Of course, the various circuits or devices may also be situated separately or in various combinations of semiconductor platforms per the desires of the user. Alternately, the parallel processing module 906 may be implemented as a circuit board substrate and each of the parallel processing unit modules and/or memory 520 modules may be packaged devices. In an embodiment, the central processing unit 902, switch 904, and the parallel processing module 906 are situated on a single semiconductor platform.

In an embodiment, the signaling rate of each NVLink 516 is 20 to 25 Gigabits/second and each parallel processing unit module includes six NVLink 516 interfaces (as shown in FIG. 9, five NVLink 516 interfaces are included for each parallel processing unit module). Each NVLink 516 provides a data transfer rate of 25 Gigabytes/second in each direction, with six links providing 300 Gigabytes/second. The NVLink 516 can be used exclusively for PPU-to-PPU communication as shown in FIG. 9, or some combination of PPU-to-PPU and PPU-to-CPU, when the central processing unit 902 also includes one or more NVLink 516 interfaces.

In an embodiment, the NVLink 516 allows direct load/store/atomic access from the central processing unit 902 to each parallel processing unit module's memory 520. In an embodiment, the NVLink 516 supports coherency operations, allowing data read from the memory 520 modules to be stored in the cache hierarchy of the central processing unit 902, reducing cache access latency for the central processing unit 902. In an embodiment, the NVLink 516 includes support for Address Translation Services (ATS), enabling the parallel processing unit module to directly access page tables within the central processing unit 902. One or more of the NVLink 516 may also be configured to operate in a low-power mode.

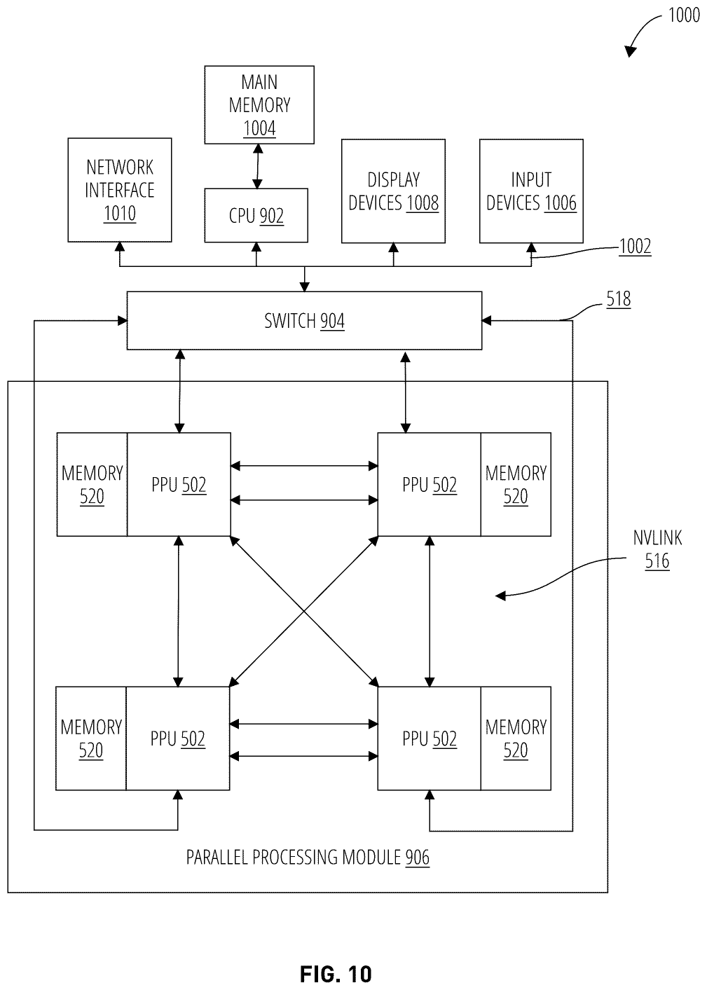

FIG. 10 depicts an exemplary processing system 1000 in which the various architecture and/or functionality of the various previous embodiments may be implemented. As shown, an exemplary processing system 1000 is provided including at least one central processing unit 902 that is connected to a communications bus 1002. The communication communications bus 1002 may be implemented using any suitable protocol, such as PCI (Peripheral Component Interconnect), PCI-Express, AGP (Accelerated Graphics Port), HyperTransport, or any other bus or point-to-point communication protocol(s). The exemplary processing system 1000 also includes a main memory 1004. Control logic (software) and data are stored in the main memory 1004 which may take the form of random access memory (RAM).

The exemplary processing system 1000 also includes input devices 1006, the parallel processing module 906, and display devices 1008, e.g. a conventional CRT (cathode ray tube), LCD (liquid crystal display), LED (light emitting diode), plasma display or the like. User input may be received from the input devices 1006, e.g., keyboard, mouse, touchpad, microphone, and the like. Each of the foregoing modules and/or devices may even be situated on a single semiconductor platform to form the exemplary processing system 1000. Alternately, the various modules may also be situated separately or in various combinations of semiconductor platforms per the desires of the user.

Further, the exemplary processing system 1000 may be coupled to a network (e.g., a telecommunications network, local area network (LAN), wireless network, wide area network (WAN) such as the Internet, peer-to-peer network, cable network, or the like) through a network interface 1010 for communication purposes.

The exemplary processing system 1000 may also include a secondary storage (not shown). The secondary storage includes, for example, a hard disk drive and/or a removable storage drive, representing a floppy disk drive, a magnetic tape drive, a compact disk drive, digital versatile disk (DVD) drive, recording device, universal serial bus (USB) flash memory. The removable storage drive reads from and/or writes to a removable storage unit in a well-known manner.

Computer programs, or computer control logic algorithms, may be stored in the main memory 1004 and/or the secondary storage. Such computer programs, when executed, enable the exemplary processing system 1000 to perform various functions. The main memory 1004, the storage, and/or any other storage are possible examples of computer-readable media.

The architecture and/or functionality of the various previous figures may be implemented in the context of a general computer system, a circuit board system, a game console system dedicated for entertainment purposes, an application-specific system, and/or any other desired system. For example, the exemplary processing system 1000 may take the form of a desktop computer, a laptop computer, a tablet computer, servers, supercomputers, a smart-phone (e.g., a wireless, hand-held device), personal digital assistant (PDA), a digital camera, a vehicle, a head mounted display, a hand-held electronic device, a mobile phone device, a television, workstation, game consoles, embedded system, and/or any other type of logic.

While various embodiments have been described above, it should be understood that they have been presented by way of example only, and not limitation. Thus, the breadth and scope of a preferred embodiment should not be limited by any of the above-described exemplary embodiments, but should be defined only in accordance with the following claims and their equivalents.

### LISTING OF DRAWING ELEMENTS

302 construct routing trees
304 initialize DAG forest
306 initialize candidate probabilities
308 determine costs and perform objective calculations
310 apply cost metric to update candidate probabilities
312 select candidates
314 assign layers
316 perform routing guided by selected candidates
402 routing trees
404 circuit nets
406 routing tree generator
408 DAG forest generator
410 DAG forest
412 L-path generator
414 candidate probability randomizer
416 candidate cost calculator
418 backpropagation function
420 candidate probability updater
502 parallel processing unit
504 I/O unit
506 front-end unit
508 scheduler unit
510 work distribution unit
512 hub
514 crossbar
516 NVLink
518 interconnect
520 memory
600 general processing cluster
602 pipeline manager
604 pre-raster operations unit
606 raster engine
608 work distribution crossbar
610 memory management unit
612 data processing cluster
614 primitive engine
616 M-pipe controller
700 memory partition unit
702 raster operations unit
704 level two cache
706 memory interface
800 streaming multiprocessor
802 instruction cache
804 scheduler unit
806 register file
808 core
810 special function unit
812 load/store unit
814 interconnect network
816 shared memory/L1 cache
818 dispatch
900 processing system
902 central processing unit
904 switch
906 parallel processing module
1000 exemplary processing system
1002 communications bus
1004 main memory
1006 input devices
1008 display devices
1010 network interface
1100 graphics processing pipeline
1102 output data
1104 data assembly
1106 vertex shading
1108 primitive assembly
1110 geometry shading
1112 viewport SCC
1114 rasterization
1116 fragment shading
1118 raster operations
1120 input data

Various functional operations described herein may be implemented in logic that is referred to using a noun or noun phrase reflecting said operation or function. For example, an association operation may be carried out by an “associator” or “correlator”. Likewise, switching may be carried out by a “switch”, selection by a “selector”, and so on. “Logic” refers to machine memory circuits and non-transitory machine readable media comprising machine-executable instructions (software and firmware), and/or circuitry (hardware) which by way of its material and/or material-energy configuration comprises control and/or procedural signals, and/or settings and values (such as resistance, impedance, capacitance, inductance, current/voltage ratings, etc.), that may be applied to influence the operation of a device. Magnetic media, electronic circuits, electrical and optical memory (both volatile and nonvolatile), and firmware are examples of logic. Logic specifically excludes pure signals or software per se (however does not exclude machine memories comprising software and thereby forming configurations of matter). Logic symbols in the drawings should be understood to have their ordinary interpretation in the art in terms of functionality and various structures that may be utilized for their implementation, unless otherwise indicated.

Within this disclosure, different entities (which may variously be referred to as “units,” “circuits,” other components, etc.) may be described or claimed as “configured” to perform one or more tasks or operations. This formulation—[entity] configured to [perform one or more tasks]—is used herein to refer to structure (i.e., something physical, such as an electronic circuit). More specifically, this formulation is used to indicate that this structure is arranged to perform the one or more tasks during operation. A structure can be said to be “configured to” perform some task even if the structure is not currently being operated. A “credit distribution circuit configured to distribute credits to a plurality of processor cores” is intended to cover, for example, an integrated circuit that has circuitry that performs this function during operation, even if the integrated circuit in question is not currently being used (e.g., a power supply is not connected to it). Thus, an entity described or recited as “configured to” perform some task refers to something physical, such as a device, circuit, memory storing program instructions executable to implement the task, etc. This phrase is not used herein to refer to something intangible.

The term “configured to” is not intended to mean “configurable to.” An unprogrammed FPGA, for example, would not be considered to be “configured to” perform some specific function, although it may be “configurable to” perform that function after programming.

Reciting in the appended claims that a structure is “configured to” perform one or more tasks is expressly intended not to invoke 35 U.S.C. § 112(f) for that claim element. Accordingly, claims in this application that do not otherwise include the “means for” [performing a function] construct should not be interpreted under 35 U.S.C § 112(f).

As used herein, the term “based on” is used to describe one or more factors that affect a determination. This term does not foreclose the possibility that additional factors may affect the determination. That is, a determination may be solely based on specified factors or based on the specified factors as well as other, unspecified factors. Consider the phrase “determine A based on B.” This phrase specifies that B is a factor that is used to determine A or that affects the determination of A. This phrase does not foreclose that the determination of A may also be based on some other factor, such as C. This phrase is also intended to cover an embodiment in which A is determined based solely on B. As used herein, the phrase “based on” is synonymous with the phrase “based at least in part on.”

As used herein, the phrase “in response to” describes one or more factors that trigger an effect. This phrase does not foreclose the possibility that additional factors may affect or otherwise trigger the effect. That is, an effect may be solely in response to those factors, or may be in response to the specified factors as well as other, unspecified factors. Consider the phrase “perform A in response to B.” This phrase specifies that B is a factor that triggers the performance of A. This phrase does not foreclose that performing A may also be in response to some other factor, such as C. This phrase is also intended to cover an embodiment in which A is performed solely in response to B.

As used herein, the terms “first,” “second,” etc. are used as labels for nouns that they precede, and do not imply any type of ordering (e.g., spatial, temporal, logical, etc.), unless stated otherwise. For example, in a register file having eight registers, the terms “first register” and “second register” can be used to refer to any two of the eight registers, and not, for example, just logical registers 0 and 1.

When used in the claims, the term “or” is used as an inclusive or and not as an exclusive or. For example, the phrase “at least one of x, y, or z” means any one of x, y, and z, as well as any combination thereof.

As used herein, a recitation of “and/or” with respect to two or more elements should be interpreted to mean only one element, or a combination of elements. For example, “element A, element B, and/or element C” may include only element A, only element B, only element C, element A and element B, element A and element C, element B and element C, or elements A, B, and C. In addition, “at least one of element A or element B” may include at least one of element A, at least one of element B, or at least one of element A and at least one of element B. Further, “at least one of element A and element B” may include at least one of element A, at least one of element B, or at least one of element A and at least one of element B.

Although the terms “step” and/or “block” may be used herein to connote different elements of methods employed, the terms should not be interpreted as implying any particular order among or between various steps herein disclosed unless and except when the order of individual steps is explicitly described.

Having thus described illustrative embodiments in detail, it will be apparent that modifications and variations are possible without departing from the scope of the intended invention as claimed. The scope of inventive subject matter is not limited to the depicted embodiments but is rather set forth in the following Claims.

What is claimed is:

1. A method for generating metal routing guides in a circuit, the method comprising:
forming a plurality of directed acyclic graphs (DAGs) embodying routing trees for nets in the circuit;
generating 2-pin subnets and 2-pin path candidates from the routing trees;
forming a DAG forest from the routing trees, the 2-pin subnets, and the 2-pin path candidates;
associating probabilities with each of the 2-pin path candidates;
refining the probabilities through repeated application of a deep learning network;
selecting a subset of the 2-pin path candidates based on the probabilities; and
configuring the subset of the 2-pin path candidates as the metal routing guides for the circuit.

2. The method of claim 1, wherein the 2-pin path candidates are formed as L-shaped paths.

3. The method of claim 1, further comprising:
assigning initial settings for the probabilities randomly.

4. The method of claim 1, wherein the deep learning network comprises a Gumbel Softmax layer.

5. The method of claim 4, wherein the Gumbel Softmax layer is configured to introduce temperature annealing effects into its outputs.

6. The method of claim 1, wherein refining the probability of a 2-pin path candidate comprises:
determining a cost of the 2-pin path candidate; and
updating the probability of the 2-pin path candidate based on the cost.

7. The method of claim 6, wherein the cost of the 2-pin path candidate is determined as a weighted sum of wire length cost, via count cost, and overflow cost for the 2-pin path candidate.

8. The method of claim 7, wherein the wire length cost, via count cost, and overflow cost are each based on a probability of selecting the 2-pin path candidate and a probability of selecting a routing tree topology comprising the 2-pin path candidate.

9. A computer system configured to generate metal routing guides in a circuit, the system comprising:
at least one graphics processing unit;
a non-transitory memory comprising instructions that when applied to the at least one graphics processing unit, configure the computer system to:
form a directed acyclic graph (DAG) forest from 2-pin subnets and 2-pin path candidates of a circuit net;
associate probabilities with each of the 2-pin path candidates;
refine the probabilities through repeated application of a deep learning network;
select a subset of the 2-pin path candidates based on the probabilities; and
configure the subset of the 2-pin path candidates as the metal routing guides for the circuit.

10. The computer system of claim 9, wherein the 2-pin path candidates consist of L-shaped paths.

11. The computer system of claim 9, wherein the instructions further configure the computer system to:
assign initial settings for the probabilities randomly.

12. The computer system of claim 9, wherein the deep learning network comprises a Gumbel Softmax layer.

13. The computer system of claim 12, wherein the Gumbel Softmax layer is configured to introduce temperature annealing effects into its outputs.

14. The computer system of claim 9, wherein refining the probability of a 2-pin path candidate comprises:
determining a cost of the 2-pin path candidate; and
updating the probability of the 2-pin path candidate based on the cost.

15. The computer system of claim 14, wherein the cost of the 2-pin path candidate is determined as a weighted sum of wire length cost, via count cost, and overflow cost for the 2-pin path candidate.

16. The computer system of claim 15, wherein the wire length cost, via count cost, and overflow cost are each based on a probability of selecting the 2-pin path candidate and a probability of selecting a routing tree topology comprising the 2-pin path candidate.

17. A non-transitory machine-readable medium comprising instructions that, when applied to at least one computer processor of a computer system, configured the computer system to:
form a directed acyclic graph (DAG) forest from 2-pin subnets and 2-pin path candidates of a circuit net;
associate probabilities with each of the 2-pin path candidates;
refine the probabilities through repeated application of a deep learning network;
select a subset of the 2-pin path candidates based on the probabilities; and
configure the subset of the 2-pin path candidates as the metal routing guides for the circuit.

18. The non-transitory machine-readable medium of claim 17, wherein the deep learning network comprises a Gumbel Softmax layer.

19. The non-transitory machine-readable medium of claim 18, wherein the Gumbel Softmax layer is configured to introduce temperature annealing effects into its outputs.

20. The non-transitory machine-readable medium of claim 17, wherein refining the probability of a 2-pin path candidate comprises:
determining a cost of the 2-pin path candidate; and
updating the probability of the 2-pin path candidate based on the cost.
